(19) United States
(12) Patent Application Publication
(10) Pub. No.: US 2014/0266278 A1
(43) Pub. Date: Sep. 18, 2014

(54) PROBE NEEDLE

(71) Applicant: CHENG YUN TECHNOLOGY CO., LTD., New Taipei City (TW)

(72) Inventor: Yun-Meng YEH, New Taipei City (TW)

(73) Assignee: CHENG YUN TECHNOLOGY CO., LTD., New Taipei City (TW)

(21) Appl. No.: 13/845,775

(22) Filed: Mar. 18, 2013

(51) Int. Cl. G01R 1/067

(52) U.S. Cl. CPC G01R 1/06722
USPC 324/755.05; 324/755.11

(57) ABSTRACT

A probe needle for connecting to a circuit board for inspection and to an inspection main board of a testing apparatus includes a conductive shaft having two ends of a connection end and an inspection end for contacting with the circuit board for inspection. An elastic conductive rod is axially connected to the conductive shaft and having two ends of a free end and a fixed end; wherein the free end is connected to the connection end of the conductive shaft and the fixed end abuts the inspection main board. The probe needle has a simplified structure facilitating the manufacturing of parts and assembly thereof.

### BACKGROUND OF THE INVENTION

1. Field of the Invention

The present invention relates to a probe needle, in particular, to a semiconductor testing probe needle used for circuit inspection.

2. Description of Related Art

Probe cards are commonly used as a means for circuit inspection in the semiconductor manufacturing process, which mostly consist of arrays of probe needles. The arrangement of the probe needles are configured corresponding to the circuit layout on the circuit board to be inspected with the probe card. Typically, the probe card is positioned on an inspection machinery and the circuit board for inspection is pressed onto the probe needles by a fixture clamp. Therefore, each one of the probe needles is electrically connected to the circuit board for inspection and the circuitry on the circuit board being inspected can be tested to determine its proper functioning and connections.

Known structure of a probe needle mostly comprises a sleeve having two electrodes with a spring connected between the two electrodes. One of the electrodes is fixed onto the inspection machinery and is electrically connected thereto; whereas the other electrode is moveably arranged inside the sleeve and is provided to be electrically connected to the circuit board for inspection. When a wafer touches the probe needle, the spring is compressed and exerts a force onto the moveable electrode such that the electrode is ensured to be in contact with the circuit board and is electrically connected thereto. Alternatively, the probe needle may comprise one movable electrode only and the spring can be used for providing an electrical connecting electrode with the inspection machinery. The probe needle is a tiny component and is often with a complex structure, which poses difficulties to the manufacturing of the parts and the assembly thereof.

In view of the above, the inventor seeks to overcome the aforementioned drawbacks of known arts and provides an improvement after extensive research and development as one of the objectives of the present invention.

### SUMMARY OF THE INVENTION

An objective of the present invention is to provide a probe needle with a simplified structure.

To achieve the aforementioned objective, the present invention provides a probe needle provided in a testing apparatus and electrically connected to the testing apparatus and to a circuit board for inspection; wherein the testing apparatus comprises an inspection main board. The probe needle of the present invention comprises a conductive shaft and an elastic conductive rod. The conductive shaft includes two ends of a connection end and an inspection end for contacting with the circuit board for inspection. The elastic conductive rod is axially connected to the conductive shaft and includes two ends of a free end connected to the connection end and a fixed end abutting the inspection main board.

Preferably, according to the aforementioned probe needle, the elastic conductive rod is a soft rod comprising a plurality of metal particles embedded therein.

Preferably, according to the aforementioned probe needle, the elastic conductive rod is a soft rod comprising a metal wire embedded therein.

Preferably, according to the aforementioned probe needle, the elastic conductive rod covers the conductive shaft.

Preferably, according to the aforementioned probe needle, the conductive shaft comprises at least one anti-slip portion; the anti-slip portion extends from a lateral side of the conductive shaft; and the free end of the elastic conductive rod covers the anti-slip portion.

Preferably, according to the aforementioned probe needle, the conductive shaft comprises a restricting portion; the restricting portion extends from a lateral side of the conducive shaft and the restricting portion rests against an inner side of the probe needle to restrict a movement schedule of the conductive shaft.

Preferably, the aforementioned probe needle further comprises a spring column sleeved externally onto the elastic conductive rod.

Preferably, according to the aforementioned probe needle, the spring column abuts the restricting portion.

The probe needle of the present invention utilizes an elastic conducive rod in replacement of the structure of a spring with a sleeve column adapted by known arts such that the drawbacks of the known arts having a complicated structure that poses difficulties to the manufacturing of the parts and the assembly thereof can be advantageously overcome.

### BRIEF DESCRIPTION OF DRAWING

FIG. 1 is an exploded view of a first embodiment of the probe needle of the present invention;

FIG. 2 is an axial cross-sectional view of the first embodiment of the probe needle of the present invention shown in FIG. 1;

FIG. 3 is an illustration showing the configuration of the first embodiment of the probe needle of the present invention;

FIG. 4 is an illustration showing the state of use of the first embodiment of the probe needle of the present invention;

FIG. 5 is an illustration showing the configuration of a second embodiment of the probe needle of the present invention;

FIG. 6 is an illustration showing the state of use of the second embodiment of the probe needle of the present invention;

FIG. 7 is an exploded view of a third embodiment of the probe needle of the present invention;

FIG. 8 is an illustration showing the configuration of the third embodiment of the probe needle of the present invention; and

FIG. 9 is an illustration showing the state of use of the third embodiment of the probe needle of the present invention.

### DETAILED DESCRIPTION OF THE INVENTION

Please refer to FIG. 1 and FIG. 2. As shown in the figures, a preferred embodiment of the present invention provides a probe needle comprising a conductive shaft 100 and an elastic conductive rod 200.

The conductive shaft 100 is preferably made of a metal material. Two ends of the conductive shaft 100 are a connection end 110 and an inspection end 120. In addition, the conductive shaft 100 further comprises an anti-slip portion 130 and a restricting portion 140. The connection end 110 is used for connecting with the elastic conductive rod 200, and an end portion of the inspection end 120 comprises a conductive contact 121. The conductive contact 121 can be either of a cut-out slot or an arched-surface protrusion shape but the present invention is not limited to such shapes. The anti-slip portion 130 is arranged between the connection end 110 and the inspection end 120 and extends outward from the mid-section of the side wall of the conductive shaft 100, and preferably, it extends outward in a shape of a circumferential rib. The restricting portion 140 extends outward from the lateral side of the conductive shaft 100, and the restricting portion 110 is preferably of a shape of a round column. In this embodiment, the anti-slip portion 130 is arranged to be adjacent to the connection end 110 whereas the restricting portion 140 is arranged to be adjacent to the inspection end 120 but the present invention is not limited to such arrangements only.

In this embodiment, the elastic conductive rod 200 is a soft rod and is preferably made of a silicon or rubber. In addition, the elastic conductive rod 200 comprises a plurality of metal particles embedded therein; for example, it can be made via solidification of silicon or rubber liquids mixed with metal powders, but the present invention is not limited to such configuration. The elastic conductive rod 200 is axially connected to the conductive rod 100. Two ends of the elastic conductive rod 200 are a free end 210 and a fixed end 220. The free end 210 is fixedly connected to the connection end 110 of the conductive shaft 100 whereas the fixed end 220 extends toward an inspection main board 20. The free end 210 of the elastic conductive rod 200 covers the connection end 110 of the conductive shaft 100 and, preferably, it covers the anti-slip portion 130 such that the elastic conductive rod 200 can be prevented from slipping off the conductive shaft 100. The elastic conductive rod 200 is further provided with a mounting hole 211 along an axis of the free end 210 for mounting onto the connection end 110 of the conductive shaft 100. Alternatively, the elastic conductive rod 200 can be formed by injection molding to cover the connection end 110 of the conductive shaft but the present invention is not limited to such configurations.

Please refer to FIG. 3, the probe needle of the present invention is installed onto a testing apparatus 10 for inspecting a circuit board for inspection 40 and the circuit board for inspection 40 comprises soldering points 41. The aforementioned testing apparatus 10 comprises an inspection main board 20 and a probe needle base 30 connected to the inspection main board 20. The inspection main board 20 includes an inspection circuitry (not shown in the figure) thereon; the probe needle base 30 comprises a plurality of needle holes 31 arranged in an array formed thereon. In addition, one opening end of each one of the needle holes 31 faces toward the inspection main board 20 and is arranged corresponding to the layout of the inspection circuitry. The semiconductor testing probe needle of the present invention is received in one of the needle holes 31. The inspection end 120 of the conductive shaft 100 is arranged to protrude outward from the needle hole 31, and the conductive contact 121 of the inspection end 120 contacts the circuit board for inspection 40. Preferably, an inner side of the needle hole 31 comprises a protruding edge 32 and the protruding edge 32 is arranged corresponding to the restricting portion 140 of the conductive shaft 100. The restricting portion 140 rests against the protruding edge 32 in order to restrict the axial movement schedule of the conductive shaft 100. The fixed end 220 the elastic conductive rod 200 abuts the inspection main board 20.

As shown in FIG. 4, when the testing apparatus 10 is used for inspecting the circuit board for inspection 40, the circuit board for inspection 40 moves toward the testing apparatus 10 such that the soldering point 41 on the circuit board for inspection 40 is in contact with the inspection end 120 of the conductive shaft 100. The soldering point 41 is preferably inserted into the conductive contact 121 of the inspection end 120 such that the inspection end 120 is ensured to be in contact with the soldering point 41 and is electrically connected thereto. Therefore, once the conductive shaft 100 is under compression, the inspection end 120 is able to retract into the needle hole 31 and the elastic conductive rod 200 is compressed axially due to the compression caused by the anti-slip portion 130 such that the circuit board for inspection 40 is electrically connected to the inspection circuitry on the inspection main board 20.

FIG. 5 and FIG. 6 show a second embodiment of a probe needle of the present invention that is of a structure, in general, similar to the one of the first embodiment recited above. This embodiment differs from the aforementioned first embodiment in that the elastic conductive rod 200 comprises a metal wire 201 embedded therein such that the metal wire 201 is electrically connected to the two ends of the elastic conductive rod 200. When the testing apparatus is used for inspecting the circuit board for inspection 40, the two ends of the metal wire 201 are electrically connected to the connection end 110 of the conductive shaft 100 and the inspection circuitry on the inspection main board 20 respectively such that the circuit board for inspection 40 is electrically connected to the inspection circuitry on the inspection main board 20.

FIG. 7 shows a third embodiment of a probe needle of the present invention that is of a structure, in general, similar to the one of the first embodiment recited above. This embodiment differs from the aforementioned first embodiment in that the probe needle of the present invention further comprises a spring column 300, and the spring column is sleeved externally onto the elastic conductive rod 200.

As shown in FIG. 8, the restricting portion 140 and the spring column 300 are both received inside the protruding edge 32. In addition, the restricting portion 140 rests against the upper blocking wall 333 whereas the spring column 300 rests between and abuts the lower blocking wall 34 and the restricting portion 140 such that the axial movement schedule of the conductive shaft 100 is restricted and such that the position of the conductive shaft 100 is secured within the needle hole 31.

As shown in FIG. 9, in this embodiment, when the testing apparatus 10 is used for inspecting the circuit board for inspection 40, the circuit board for inspection 40 moves toward the testing apparatus 10 such that the soldering point 41 on the circuit board for inspection 40 contacts the inspection end 120 of the conductive shaft 100. The soldering point 41 is preferably inserted into the conductive contact 121 of the inspection end 120 in order to ensure that the inspection end 120 is in contact with the soldering point 41 and is electrically connected thereto. As the circuit board for inspection 40 moves closer to force the inspection end 120 to press onto the circuit board for inspection 40, the conductive shaft 100 is under compression such that the inspection end 120 retracts into the needle hole 31 and the elastic conductive rod 200 is compressed axially due to the compression caused by the anti-slip portion 130; during which, the spring column 300 is also being compressed axially due to the compression caused by the restricting portion 140 such that the circuit board for inspection 40 is electrically connected to the inspection circuitry of the inspection main board 20. In this embodiment, the stability of the activation movement of the conductive shaft 100 is enhanced as the additional spring column 300 provides its aid to the elastic conductive rod 200.

The probe needle of the present invention utilizes the elastic conductive rod 200 in replacement of the structure of a spring with a sleeve adapted by known arts. As a result, the probe needle of the present invention is of a simplified structure facilitating the manufacturing of parts and assembly thereof in light of overcoming the drawbacks of the known arts.

It can be understood that the preferred embodiments of the present invention are provided for illustrative purposes only, which shall not be used to limit the scope of the present invention. Any other modifications and variations in relation to the spirit of the present invention and capable of generating substantially equivalent outcomes shall all be considered to be within the scope of the present invention.

What is claimed is:

1. A probe needle provided in a testing apparatus and electrically connected to both said testing apparatus and to a circuit board for inspection; said testing apparatus comprising an inspection main board and said probe needle comprising:
a conductive shaft having two ends of a connection end and an inspection end for contacting with said circuit board for inspection; and
an elastic conductive rod axially connected to said conductive shaft and having two ends of a free end connected to said connection end and a fixed end abutting said inspection main board.

2. The probe needle according to claim 1, wherein said elastic conductive rod is a soft rod comprising a plurality of metal particles embedded therein.

3. The probe needle according to claim 1, wherein said elastic conductive rod is a soft rod comprising a metal wire embedded therein.

4. The probe needle according to claim 1, wherein said elastic conductive rod covers said conductive shaft.

5. The probe needle according to claim 1, wherein said conductive shaft comprises at least one anti-slip portion; said anti-slip portion extends from a lateral side of said conductive shaft; and said free end of said elastic conductive rod covers said anti-slip portion.

6. The probe needle according to claim 1, wherein said conductive shaft comprises a restricting portion; said restricting portion extends from a lateral side of said conducive shaft and said restricting portion rests against an inner side of said probe needle to restrict a movement schedule of said conductive shaft.

7. The probe needle according to claim 6, further comprising a spring column sleeved externally onto said elastic conductive rod.

8. The probe needle according to claim 7, wherein said spring column abuts said restricting portion.

9. The probe needle according to claim 1, further comprising a spring column sleeved externally onto said elastic conductive rod.
